(19) United States
(12) Patent Application Publication
(10) Pub. No.: US 2008/0157344 A1
(43) Pub. Date: Jul. 3, 2008

(54) Heat dissipation semiconductor pakage

(75) Inventors: Chin-Te Chen, Taichung Hsien (TW); Ke-Chuan Yang, Taichung Hsien (TW); Chung-Hsing Ko, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/732,866

(22) Filed: Apr. 4, 2007

(30) Foreign Application Priority Data
Dec. 28, 2006 (TW) 095149396

(51) Int. Cl. H01L 23/34

(52) U.S. Cl. 257/706; 257/E23.08

(57) ABSTRACT

A heat dissipation semiconductor package is disclosed according to the present invention. The heat dissipation semiconductor package comprises: a substrate that has a plurality of solder pads and at least one ground pad; a semiconductor chip that is mounted on the substrate and electrically connects to the solder pads; a plurality of passive elements that are mounted on the solder pads of the substrate; at least one metal bump or passive element of zero resistance, which are mounted on the at least one ground pad of the substrate; and a heat sink, which is capable of being mounted on the passive elements, and the at least one passive element of zero resistance or the metal bump, and the heat sink is electrically connecting to the at least one passive element of zero resistance or the metal bump, and then is further electrically coupling with the at least one ground pad of the substrate to form a ground return circuit, thus provides a shielding effect on electromagnetic interference (EMI).

### BACKGROUND OF THE INVENTION

1. Field of the Invention

This invention generally relates to a semiconductor package, and more specifically, to a semiconductor package that has a heat dissipation structure integrated therewith.

2. Description of Related Art

Along with the demand for lighter and smaller electronic products, and since it is capable of providing sufficient amount of input/output connections for coping with the demand of semiconductor chips that have high integration electronic components and electronic circuits, ball grid array (BGA) semiconductor package has gradually become the mainstream of package productions. However, since this semiconductor package is capable of providing higher density electronic circuits and electronic components, the heat generated due to operation is higher, if heat around the surface of a chip can not be dissipated immediately, the accumulated heat will further affect the electried performance and product stability of the semiconductor chip.

In order to solve the problem of heat dissipation insufficiency of the ball grid array semiconductor package as in prior art, techniques of integrating heat dissipation structure to the BGA semiconductor package have been presented accordingly. Related prior art includes U.S. Pat. Nos. 5,877,552, 5,736,785, 5,977,626, 5,851,337, 6,552,428, 6,246,115, 6,429,512, 6,400,014, 6,462,405 and others.

As shown in FIG. 1, which illustrates a heat dissipation semiconductor package according to the claims of U.S. Pat. No. 5,977,626, the heat dissipation structure 13 of the heat dissipation semiconductor package 1 comprises: a level section 130, whose top surface is uncovered from a encapsulant 14; a plurality of support sections 131, which support the level section 130 to be hanged above a semiconductor chip 11; a plurality of contact sections 132, which extend from the bottoms of the support sections 131 and provide a plurality of raised sections 137 for gluing to a substrate 10; wherein, the support sections 131 are installed around the rim of the level section 130 and gradually extend downward and outward until reach the contact sections 132, and then form a trough-shaped compartment that is capable of containing a plurality of active/passive elements, such as chips, bonding wires, capacitors, and others, thus the heat generated due to the operation of the chip 11 can be dissipated into the air via the heat dissipation structure 13.

However, along with the well-developed chip integration and chip scale package (CSP), the demanded size of the substrate has become close to a near chip size, if take both reducing substrate size and increasing integration density of bonding wires into consideration, the substrate must provide more available space for components integration from its limited surface area. To cope with the formation of the aforementioned raised sections 137 of the heat dissipation structure 13, the contact sections 132 have to save a certain area in favor of fabricating the raised sections 137, and the contact sections 132 of the heat dissipation structure 13 also take more space of the substrate, not only affects the installation of the substrate circuits, but also limits the layout of the passive elements.

In addition, since the margins of the substrate is taken by the contact sections 132, all the active/passive elements of the package can only be laid inside the trough-shaped compartment 18 formed by the support sections 131 and the level section 130, therefore, if the substrate area taken by the contact sections 132 can not be reduced, the relative substrate area provided for installing the active/passive element is obviously insufficient, thus this kind of heat dissipation structure 13 is not applicable to a package of high integration.

Please refer to FIGS. 2A and 2B, in view of the forgoing drawbacks, a heat dissipation semiconductor package and its fabrication method is disclosed according to U.S. Publication No. 20060242741, wherein, a semiconductor chip 21 and a plurality of passive elements 29 are mounted on and electrically connect to a substrate 200, and then a heat dissipation structure 22 that has a level section 221 and a plurality of support sections 222 is mounted on the substrate 200 via the support sections 222, thus the semiconductor chip 21 is mounted under the level section 221, wherein, the support sections 222 are connectedly installed on the substrate 200 outside the predetermined planar size of the semiconductor chip P (as shown in FIG. 2A); next, an encapsulant 23 is formed on the substrate that has the semiconductor chip 21 and the heat dissipation structure 22 to encapsulate the semiconductor chip 21 and the heat dissipation structure 22, and the projection planar size of the encapsulant M is larger than the predetermined planar size of the semiconductor chip P, next, cut along the outline of the predetermined planar size of the semiconductor chip P to remove the support sections of the encapsulant and heat dissipation structure and the part of the substrate beyond the predetermined planar size of the semiconductor chip (as shown in FIG. 2B).

By mounting the support sections of the heat dissipation structure on the substrate beyond the predetermined planar size of the semiconductor chip, this prior art prevents from taking up substrate circuit layout space available for mounting and electrically connecting to electronic components of, such as the semiconductor chip and passive elements and others, and further provides these electronic components with sufficient substrate mounting space.

However, in the abovementioned heat dissipation semiconductor package, the support sections of the heat dissipation structure are located on beyond the predetermined planar size of the semiconductor chip, in other words, the support sections are not inside the semiconductor package after the cutting process, therefore, the heat dissipation structure itself is not capable of being mounted on and electrically connecting to the substrate mounting area to form a ground return circuit for further providing a shielding effect on electromagnetic interference (EMI).

In addition, although U.S. Pat. No. 5,877,552 discloses that a heat dissipation structure is mounted on and electrically connects to a substrate mounting area via its plurality of support sections, and the support sections are directly mounted on inside the semiconductor package, thus this prior art has the same aforementioned drawbacks of wasting substrate space as well as limiting the layout of passive elements. In other words, the heat dissipation structure still relies on the support sections for support in order to be mounted on the substrate and thereby wasting precious substrate space.

Furthermore, the heat dissipation structure of each of the aforementioned prior art has support sections for mounting the heat dissipation structure on a substrate, and the support sections cost more material and labor and thus increase the production cost. Hence, it is a highly urgent issue in the industry for how to provide a technique which can effectively solve the heat dissipation problem of semiconductor package, and meanwhile provide a shielding effect on electromagnetic interference for the semiconductor package, and also avoid the problem that the heat dissipation structure takes up substrate area as well as the problems of wasting material and high production cost.

### SUMMARY OF THE INVENTION

In view of the disadvantages of the prior art as mentioned above, it is a primary objective of the present invention to provide a heat dissipation semiconductor package, which is capable of preventing the heat dissipation structure that is integrated to the semiconductor package from limiting the layout space of electronic components.

It is another objective of the present invention to provide a heat dissipation semiconductor package, which is capable of providing a shielding effect on electromagnetic interference.

It is a further objective of the present invention to provide a heat dissipation semiconductor package, which is capable of avoiding the problems of wasting material and high production cost caused by using a heat dissipation structure that has support sections.

To achieve the aforementioned and other objectives, a heat dissipation semiconductor package is provided according to the present invention. The heat dissipation semiconductor package comprises: a substrate, which has a plurality of solder pads and at least one ground pad on a surface thereof; a semiconductor chip, which is mounted on the substrate and electrically connects to the solder pads; a plurality of passive elements, which are mounted on the solder pads of the substrate; at least one metal bump or passive element of zero resistance, which is mounted on the at least one ground pad of the substrate; and a heat sink, which is mounted on the passive elements and electrically connects to the at least one passive element of zero resistance.

The heat dissipation semiconductor package further comprises an encapsulant that encapsulates the heat sink, the semiconductor chip, the passive elements, and the at least one passive element of zero resistance, and also has the top of the heat sink be uncovered from the encapsulant; a raised section is formed on the center of the heat sink, and the top of the raised section is uncovered from the encapsulant but the remaining part of the raised section is encapsulated by the encapsulant, thereby enhancing the bonding between the heat sink and the encapsulant. In addition, the heat sink is mounted on and electrically connects to the at least one passive element of zero resistance via conductive adhering layer, and is also mounted on the passive elements via nonconducting adhering layer.

The present invention further discloses another better embodiment of a heat dissipation semiconductor package, which comprises: a substrate, which has a plurality of solder pads and ground pads; a semiconductor chip, which is mounted on and electrically connects to the solder pads; a plurality of passive element, which are mounted on and electrically connect to the solder pads of the substrate; a plurality of metal bumps, which are mounted on and electrically connect to the ground pads of the substrate; and a heat sink, which is mounted on and electrically connects to each of the metal bumps with a conductive adhering layer in between.

In addition, the heat sink of the present invention further can be mounted on the semiconductor chip with thermal grease conductive gel in between in order to help to dissipate heat generated due to semiconductor chip operation; but in other embodiment, there can be a space between the heat sink and the semiconductor chip in order to prevent the semiconductor chip from being pressed and damaged.

In summary, in addition to mounting and electrically connecting a semiconductor chip and a plurality of passive elements to the substrate, the heat dissipation semiconductor package of the present invention mainly also sets at least one ground pad on the substrate, and at least one passive element of zero resistance or metal bump is mounted on and electrically connect to the ground pad, therefore, the heat sink is capable of electrically connecting to the at least one passive element of zero resistance or metal bump via a conductive adhering layer, and further electrically coupling with the at least one ground pad of the substrate to form a ground return circuit, thus providing a shielding effect on electromagnetic interference (EMI); furthermore, the heat sink of the present invention can be mounted on as well as get support from the passive elements and the at least one passive element of zero resistance or metal bump, and thus avoids the problems of high production cost and high amount of materials of the heat dissipation structure as in the prior art, wherein, the heat dissipation structure that has support sections is mounded on the substrate via its support sections, and the support sections also impede and limit the layout of the electronic components on the substrate.

### BRIEF DESCRIPTION OF DRAWINGS

The present invention can be more fully understood by reading the following detailed description of the preferred embodiments, with reference made to the accompanying drawings, wherein:

FIG. 1 is a sectional view diagram of a heat dissipation semiconductor package according to the claims of U.S. Pat. No. 5,977,626;

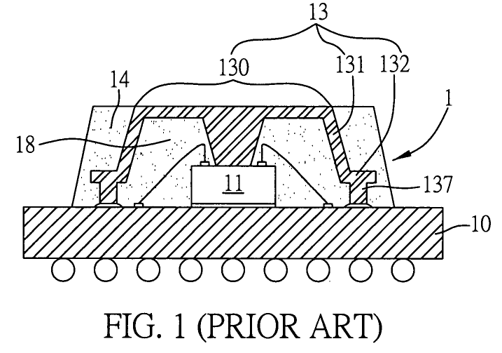

FIGS. 2A and 2B are diagrams of a heat dissipation semiconductor package and its fabrication method according to the claims of Taiwan patent no. 255047;

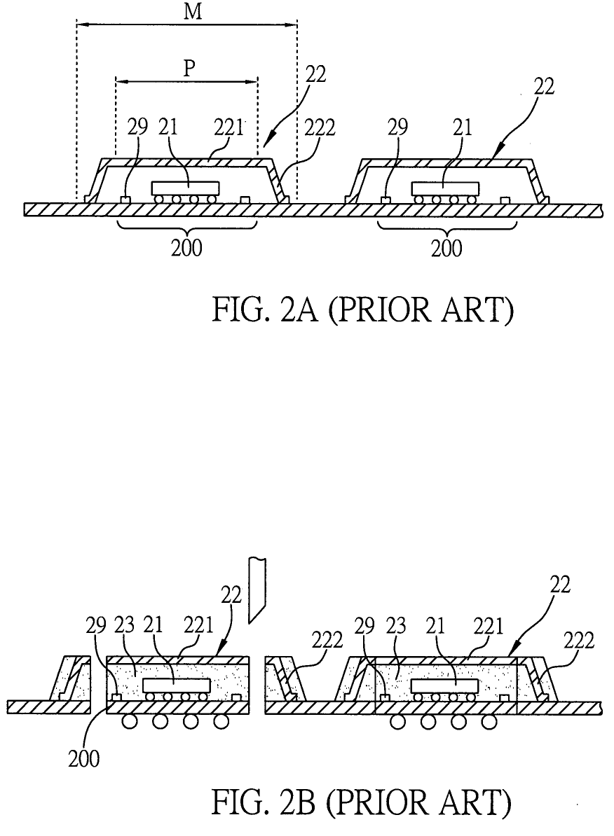

FIGS. 3A and 3B are planar view and sectional view diagrams of a first embodiment of a heat dissipation semiconductor package according to the present invention;

FIGS. 4A through 4C are diagrams of a second embodiment of a heat dissipation semiconductor package according to the present invention;

FIG. 5 is a diagram of a third embodiment of a heat dissipation semiconductor package according to the present invention; and

FIG. 6 is a diagram of a fourth embodiment of a heat dissipation semiconductor package according to the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

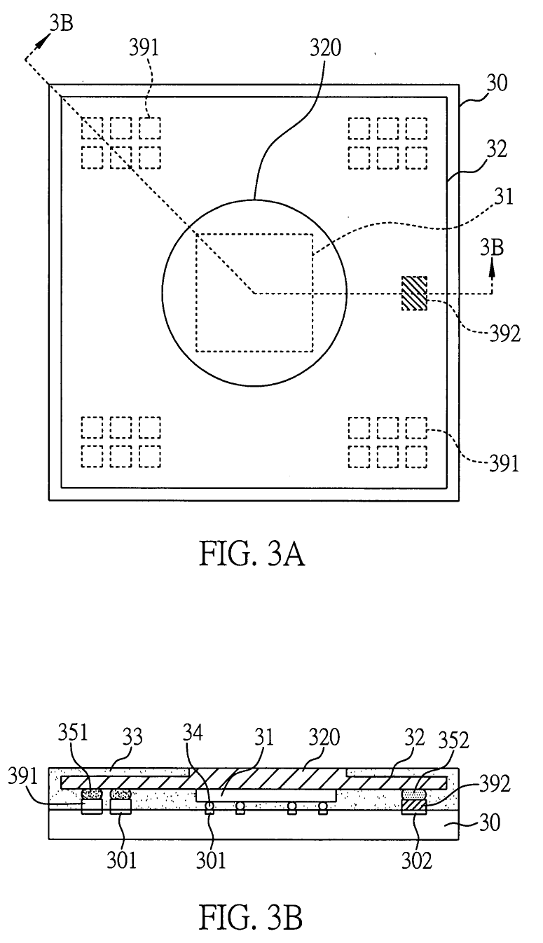

Please refer to FIGS. 3A and 3B, which are diagrams of planar view and section view of the first embodiment of a heat dissipation semiconductor package according to the present invention.

As shown in the figures, the heat dissipation semiconductor package comprises: a substrate 30, which has a plurality of solder pads 301 and at least a ground pad 302 set on a surface thereof; at least a semiconductor chip 31, which is mounted on the substrate 30 and electrically connects to the solder pads 301; a plurality of passive elements 391, which are mounted on and electrically connect to the solder pads 301 of the substrate 30; at least a passive element of zero resistance 392, which is mounted on and electrically connects to the ground pad 302; and a heat sink 32, which is mounted on the passive elements 391, and electrically connects to the passive element of zero resistance 392.

The substrate 30 can be, for example, a ball grid array substrate, and a surface of the substrate 30 has a plurality of solder pads 301 and at least a ground pad 302.

The semiconductor chip 31 can be mounted on and electrically connect to the solder pads 301 of the substrate 30 via a plurality of conductive bumps 34. And the semiconductor chip 31 can also electrically connect to the substrate by means of wire bonding as well.

Meanwhile, the substrate 30 further has a plurality of passive elements 391 mounted on atop, the passive elements 391 are, for example, resistors, capacitors, inductors, or others, and are mounted on and electrically connect to the solder pads 301 of the substrate 30 in order to enhance or improve package electrical performance.

The passive element of zero resistance 392 is mounted on and electrically connect to the ground pads 302 of the substrate 30 to provide ground effect on the heat sink 32 that later on electrically connects to the passive element of zero resistance 392.

The passive elements 391 can be pre-set on along margins or around corners of the substrate 30 and then function as the support structures of the heat sink 32 later on, and also form at least a ground pad 302 on substrate 30 area where is not taken by any regular passive elements 391 in order to provide at least a passive element of zero resistance with electricity connection to the ground pad 302.

According to the present invention, after the substrate 30 has been fully laid with semiconductor chip and passive elements 391, the heat sink 32 is mounted on each of the passive elements 391 via a nonconducting adhering layer 351, and then covers up the semiconductor chip 31 but will not restrict the layout of the semiconductor chip 31 and the passive elements 391; and the heat sink 32 further electrically connects to the passive element of zero resistance 392 via a conductive adhering layer 352, and then the heat sink 32 is capable of electrically coupling with the ground pad 302 of the substrate 30 to provide a shielding effect on electromagnetic interference for the semiconductor chip 31 that is covered under the heat sink 32; in addition, the heat sink 32 can be effectively mounted on the substrate 30 via the passive element of zero resistance 392.

In summary of the foregoing descriptions, since the heat sink 32 is mounted on the substrate 30 by means of the support of a plurality of passive elements 391 that are oppositely located on around corners or along margins of the substrate 30, thereby avoiding the problems of high production cost and high amount of materials of the heat dissipation structures as in the prior art, wherein, the heat dissipation structure that has support sections is mounded on the substrate via its support sections, and the support sections also impede and limit the layout of the electronic components on the substrate.

In addition, the heat dissipation semiconductor package further comprises an encapsulant 33 that encapsulates the heat sink 32, the semiconductor chip 31, the passive elements 391 and the passive element of zero resistance 392, and the top of the heat sink 32 is uncovered from the encapsulant 33; wherein, a raised section 320 is formed on the top of the center part of the heat sink 32, and the top of the raised section 320 is uncovered from the encapsulant 33, the remaining part of the raised section 320 is encapsulated by the encapsulant 33, thereby enhancing the bonding between the heat sink 32 and the encapsulant 33.

Furthermore, the heat dissipation semiconductor package of the present invention can further have metal bump (not shown in the figure) be mounted on and electrically connect to the ground pad 302 of the substrate 30 for replacing the passive element of zero resistance 392, thus the heat sink 32 is capable of electrically connecting to the metal bump via a conductive adhering layer and further electrically coupling with the ground pad of the substrate.

### Second Embodiment

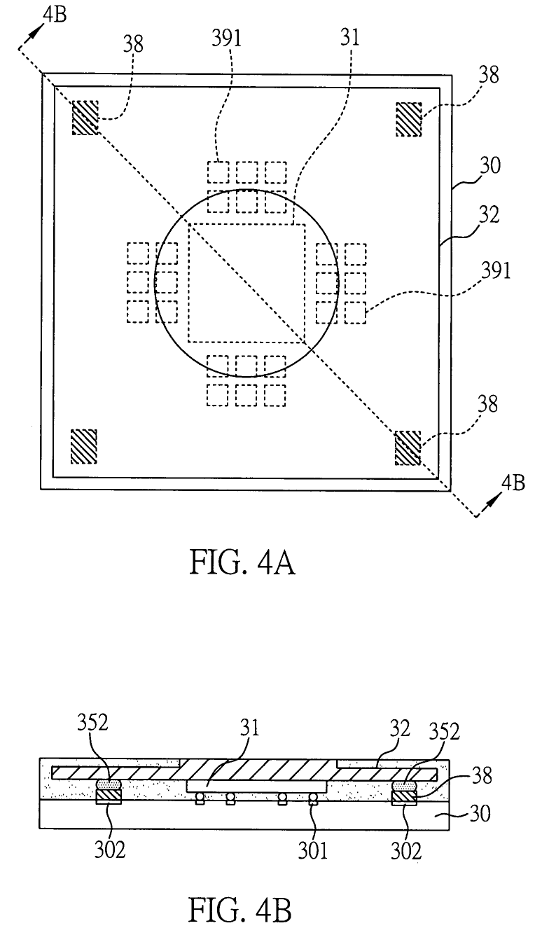

Please refer to FIGS. 4A through 4C, which are diagrams of the second embodiment of a heat dissipation semiconductor package according to the present invention, wherein, FIG. 4B is a section view diagram corresponding to the heat dissipation semiconductor package of FIG. 4A.

The heat dissipation semiconductor package disclosed in the second embodiment of the present invention is applicable to situations such as: when regular passive elements can not be used as support structures, or to prevent the regular passive elements from being damaged, in the present embodiment, a plurality of ground pads 302 are formed on around corners or along margins of the substrate 30 (as shown in FIGS. 4A and 4B), and have at least three passive elements of zero resistance or metal bumps 38 be mounted on and electrically connect to the ground pads 302, meanwhile set a plurality of solder pads 301 on other area of the substrate 30 for mounting and electrically connecting to a semiconductor chip 31 and a plurality of regular passive elements 391, and thus a heat sink 32 can be mounted on and electrically connect to each of the passive elements of zero resistance or metal bumps 38 via a conductive adhering layer 352, the passive elements of zero resistance or metal bumps 38 not only provide support for the heat sink 32 but also electrically couple with the ground pads 302 of the substrate 30 to form ground return circuits, thereby further providing the semiconductor chip with shielding effect on electromagnetic interference.

### Third Embodiment

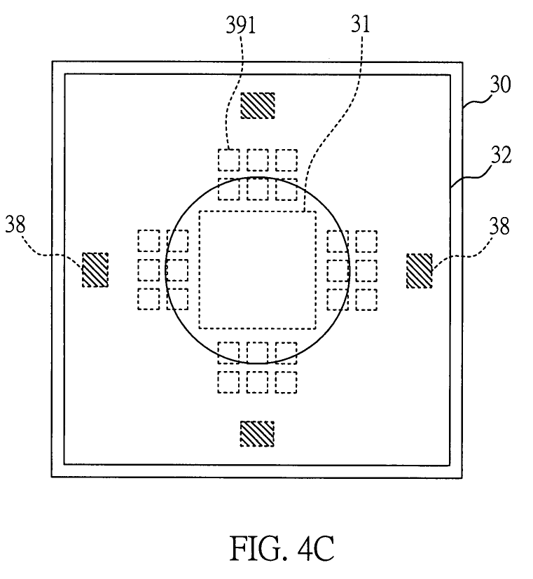

Please refer to FIG. 5, which is a diagram of the third embodiment of a heat dissipation semiconductor package of the present invention, the heat dissipation semiconductor package of the present embodiment is mostly similar to the ones of the foregoing embodiments, the main difference is that the heat sink 32 of the present invention can further be mounted on the semiconductor chip 31 via thermal grease 37, thereby helping to dissipate heat generated due to semiconductor chip operation.

### Fourth Embodiment

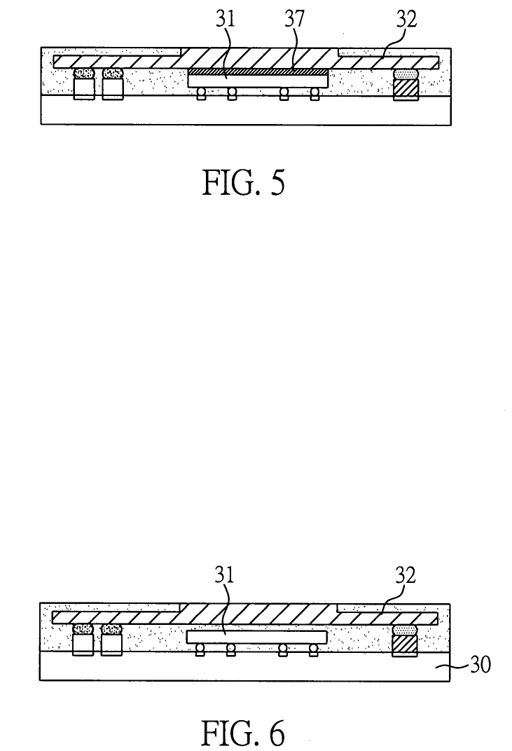

Please refer to FIG. 6, which is a diagram of the fourth embodiment of a heat dissipation semiconductor package according to the present invention, the heat dissipation semiconductor package of the present embodiment is mostly similar to the ones in the foregoing embodiments, the main difference is that in the present embodiment, there is a space between the heat sink 32 and the semiconductor chip 31 that is mounted on the substrate 30, thereby preventing the semiconductor chip 31 from being pressed and damaged.

In summary, in addition to mounting and electrically connecting a semiconductor chip and a plurality of passive elements to the substrate, the heat dissipation semiconductor package of the present invention mainly also sets at least one ground pad on the substrate, and at least one passive element of zero resistance or metal bump is mounted on and electrically connect to the ground pad, therefore, the heat sink is capable of electrically connecting to the at least one passive element of zero resistance or metal bump via a conductive adhering layer, and further electrically coupling with the at least one ground pad of the substrate to form a ground return circuit, thus providing a shielding effect on electromagnetic interference (EMI); furthermore, the heat sink of the present invention can be mounted on as well as get support from the passive elements and the at least one passive element of zero resistance or metal bump, and thus avoids the problems of high production cost and high amount of materials of the heat dissipation structure as in the prior art, wherein, the heat dissipation structure that has support sections is mounded on the substrate via its support sections, and the support sections also impede and limit the layout of the electronic components on the substrate.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A heat dissipation semiconductor package, which comprises:
a substrate, having a plurality of solder pads and at least a ground pad set on a surf ace thereof;
a semiconductor chip mounted on the substrate and electrically connected to the solder pads;
a plurality of passive components mounted on and electrically connected to the solder pads of the substrate;
at least a passive component of nearly zero resistance mounted on and electrically connected to the ground pad of the substrate; and
a heat sink mounted on and electrically connected to the passive component of nearly zero resistance.

2. The heat dissipation semiconductor package of claim 1, wherein, the heat sink is mounted on the at least one passive component of nearly zero resistance via conductive adhering layer and covers the semiconductor chip.

3. The heat dissipation semiconductor package of claim 1, wherein, the at least one passive component of nearly zero resistance is selectively set around the corners and along the margins of the heat sink.

4. The heat dissipation semiconductor package of claim 3, wherein, there are at least three passive components of nearly zero resistance.

5. The heat dissipation semiconductor package of claim 1, wherein, the heat sink is mounted on each of the passive components via a nonconducting adhering layer and covers the semiconductor chip.

6. The heat dissipation semiconductor package of claim 1, wherein, the passive components are selectively set around the corners and along the margins of the substrate, and then at least one ground pad is formed on an area of the substrate where no passive component is formed, and thus at least one passive component of nearly zero resistance can be mounted on and electrically connected to the ground pad.

7. The heat dissipation semiconductor package of claim 1, wherein, the semiconductor chip electrically connects to the substrate by means of either flip-chip or wire bonding.

8. The heat dissipation semiconductor package of claim 1, further comprising an encapsulant that is formed on the substrate to encapsulate the heat sink, the semiconductor chip, the passive components, and the passive components of nearly zero resistance, and also have the top of the heat sink be uncovered from the encapsulant.

9. The heat dissipation semiconductor package of claim 8, wherein, form a raised section on the center of the heat sink, and the top of the raised section is uncovered from the encapsulant, but the remaining part of the raised section is covered by the encapsulant in order to enhance the bonding between the heat sink and encapsulant.

10. The heat dissipation semiconductor package of claim 1, wherein, the heat sink is mounted on the semiconductor chip via thermal grease.

11. The heat dissipation semiconductor package of claim 1, wherein, there is a space between the heat sink and the semiconductor chip.

12. A heat dissipation semiconductor package, which comprises:
a substrate having a plurality of solder pads and at least one ground pad on a surface thereof;
a semiconductor chip mounted on the substrate and electrically connected to the solder pads;
a plurality of passive components mounted on and electrically connected to the solder pads of the substrate;
at least one metal bump mounted on and electrically connected to the ground pad of the substrate; and
a heat sink mounted on and electrically connected to the at least one metal bump.

13. The heat dissipation semiconductor package of claim 12, wherein, the heat sink is mounted on and electrically connects to the at least one metal bump via conductive adhering layer, and then covers the semiconductor chip.

14. The heat dissipation semiconductor package of claim 12, wherein, the at least one metal bump is selectively set on around corners or along margins of the heat sink.

15. The heat dissipation semiconductor package of claim 14, wherein, there are at least three metal bumps.

16. The heat dissipation semiconductor package of claim 12, wherein, the heat sink is mounted on each of the passive components via a nonconducting adhering layer, and then covers the semiconductor chip.

17. The heat dissipation semiconductor package of claim 12, wherein, the passive elements components are selectively set around the corners and along the margins of the heat sink.

18. The heat dissipation semiconductor package of claim 12, wherein, the semiconductor chip electrically connects to the substrate by means of either flip-chip or wire bonding.

19. The heat dissipation semiconductor package of claim 12, further comprising an encapsulant that is formed on the substrate to encapsulate the heat sink, the semiconductor chip, the passive components, and the at least one metal bump, and also have the top of the heat sink be uncovered from the encapsulant.

20. The heat dissipation semiconductor package of claim 19, wherein, form a raised section on the center of the heat sink, and the top of the raised section is uncovered from the encapsulant, the remaining part of the raised section is covered by the encapsulant in order to enhance the bonding between the heat sink and the encapsulant.

21. The heat dissipation semiconductor package of claim 12, wherein, the heat sink is mounted on the semiconductor chip via thermal grease.

22. The heat dissipation semiconductor package of claim 12, wherein, there is a space between the heat sink and the semiconductor chip.

23. The heat dissipation semiconductor package of claim 1, wherein the passive components are selected from a group consisting of resistors, capacitors, and inductors.

24. The heat dissipation semiconductor package of claim 12, wherein the passive components are selected from a group consisting of resistors, capacitors, and inductors.
